(19) United States
(12) Patent Application Publication
(10) Pub. No.: US 2020/0009721 A1
(43) Pub. Date: Jan. 9, 2020

(54) ROBOT

(71) Applicant: LG ELECTRONICS INC., Seoul (KR)

(72) Inventors: Jekwang YOUN, Seoul (KR); Seungwoo MAENG, Seoul (KR); Jaebeom IM, Seoul (KR); Dongkyu CHOI, Seoul (KR); Zhimin CHOO, Seoul (KR)

(21) Appl. No.: 16/577,575

(22) Filed: Sep. 20, 2019

Related U.S. Application Data
(63) Continuation of application No. PCT/KR2019/002604, filed on Mar. 6, 2019.

(51) Int. Cl. B25J 9/00; G03B 21/16; H05K 7/20

(52) U.S. Cl. CPC B25J 9/0009; H05K 7/20154; G03B 21/16

(57) ABSTRACT

A robot according to an embodiment of the present disclosure may include: a base; a case that is disposed over the base and has an internal space; a front cover that covers the internal space ahead of the case; a projector that is positioned in the internal space, is disposed to face a forward upper side, and projects an image or a video to the front cover; and a built-in component that is disposed ahead of the projector. The front cover may include: a display region in which an image or a video projected from the projector is displayed; and a non-display region that is positioned under the display region and overlaps the built-in component in a front-rear direction.

### CROSS-REFERENCE TO RELATED APPLICATIONS

The present application is a continuation application of PCT/KR2019/002604 (filed on 2019 Mar. 6), which is hereby incorporated by reference in its entirety.

### BACKGROUND

The present disclosure relates to a robot and, more particularly, to a robot including a projector.

Robots have been developed for the industry to take charge of a part of factory automation. Recently, as robots have been applied to more fields, not only medical robots and aerospace robots, but also robots that can be used for daily life have been developed.

Such robots for daily life provide specific services (e.g., shopping, serving, dialog, and cleaning) in response to instructions from users. Further, robots for daily life include a display, so they display information, videos, or images related to services.

However, there is a problem in that existing robots for daily life have to unavoidably include separate display panels to display information, videos, and images.

### SUMMARY

An object of the present disclosure is to provide a robot that can display videos or images on a front cover itself by projecting images to the front cover from a projector.

Another object of the present disclosure is to provide a robot that maximizes a display region of a front cover and keeps a compact size.

According to a robot according to an embodiment of the present disclosure, a projector is disposed behind a built-in component, so a focal distance of the projector can be secured and the robot can be made compact. Further, the projector is disposed to face the front upper side, so the light emitted from the projector is not blocked by the built-in component and a display region of a front cover can be maximized.

In more detail, a robot according to an embodiment of the present disclosure may include: a base; a case that is disposed over the base and has an internal space; a front cover that covers the internal space ahead of the case; a projector that is positioned in the internal space, is disposed to face a forward upper side, and projects an image or a video to the front cover; and a built-in component that is disposed ahead of the projector. The front cover may include: a display region in which an image or a video projected from the projector is displayed; and a non-display region that is positioned under the display region and overlaps the built-in component in a front-rear direction.

The robot may further include a head display that is connected to the case and faces the front. An opening in which the head display is disposed may be formed in the front cover, and the display region may surround at least a portion around the opening.

The head display may be spaced upward apart from at least one of the projector or the built-in component, and the display region may surround a portion of a lower portion around the opening.

The projector may overlap the non-display region in the front-rear direction.

An outer cover having a fabric material may be attached to the front surface of the front cover.

The case may include: a lower case that is fastened to the base; and an upper case that is connected with the upper side of the lower case. The vertical length of the upper case may be larger than the vertical length of the lower case.

The lower end of the rear portion of the lower case may protrude rearward further than the upper end of the rear portion of the lower case.

The built-in component may include a speaker that faces the front, and a plurality of sound holes through which sound of the speaker is discharged may be formed in the non-display region.

The area of the display region may be larger than the area of the non-display region.

The robot may include an inner bracket that is disposed over the projector and to which a plurality of electronic components is fastened.

The internal space may include: a first space through which light emitted from the projector to the display region passes; a second space that is positioned between the base and the first space and in which the built-in component is disposed; and a third space that is positioned between the first space and the case and in which the inner bracket is disposed.

The inner bracket may be fastened to the inner rear surface of the case, may be disposed at an angle such that the height increases forward, and may vertically overlap the projector.

The projector may be seated on the base.

The robot of claim may further include: a pair of driving motors that is disposed on the base; and a pair of driving wheels that is connected to the pair of driving motors, respectively. At least a portion of the projector may be disposed between the pair of driving motors.

The robot may further include a heat dissipation fan that is disposed under the built-in component. A plurality of heat dissipation holes through which airflow generated by the heat dissipation fan passes may be formed through the base.

The plurality of heat dissipation holes may include: a rear heat dissipation hole that is positioned under the projector; and a front heat dissipation hole that is positioned under the heat dissipation fan.

The robot may further include a projector seat panel that is connected to the base to be able to tilt and on which the projector is mounted.

A robot according to an embodiment may include: a base that has an open front surface; a projector that is disposed in the case; and a front cover that covers the open front surface of the case. The front cover may include: a display region in which a video or an image projected from the projector is displayed; and a non-display region that is positioned over or under the display region and has an area smaller than the area of the display region.

The robot may further include a head display that is connected to the case and faces the front, in which an opening in which the head display is disposed may be formed in the front cover, and the display region may surround at least a portion around the opening.

The projector may overlap the non-display region in the front-rear direction.

### BRIEF DESCRIPTION OF THE DRAWINGS

The above and other objects, features and other advantages of the present disclosure will be more clearly understood from the following detailed description when taken in conjunction with the accompanying drawings, in which:

FIG. 1 is a perspective view of a robot according to an embodiment of the present disclosure;

FIG. 2 is a side view of the robot according to an embodiment of the present disclosure;

FIG. 3 is a bottom view of the robot according to an embodiment of the present disclosure;

FIG. 4 is a view showing the robot according to an embodiment of the present disclosure with a front cover removed;

FIG. 5 is an exploded perspective view of the robot according to an embodiment of the present disclosure;

FIG. 6 is a view illustrating a base, and a projector and built-in components seated in the base according to an embodiment of the present disclosure;

FIG. 7 is a view illustrating an inner bracket and electronic components mounted on the inner bracket according to an embodiment of the present disclosure;

FIG. 8 is a front view showing a display region and a non-display region of a front cover according to an embodiment of the present disclosure;

FIG. 9 is a cross-sectional view showing the inside of the robot according to an embodiment of the present disclosure; and

FIG. 10 is a view enlarging the portion A of FIG. 9.

### DETAILED DESCRIPTION OF THE DISCLOSURE

Hereinafter, detailed embodiments of the present disclosure will be described in detail with reference to the accompanying drawings.

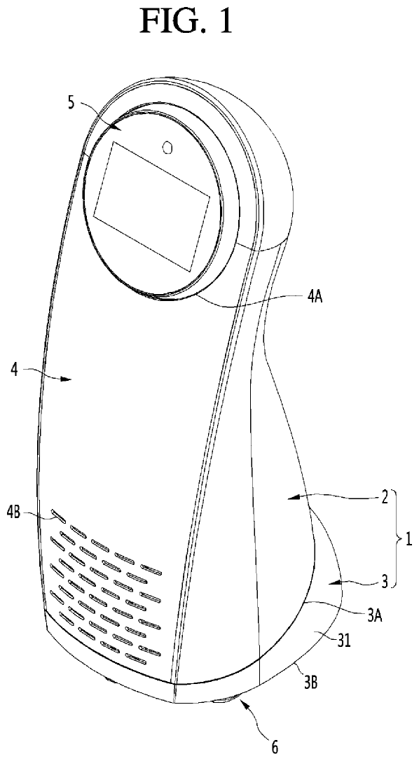

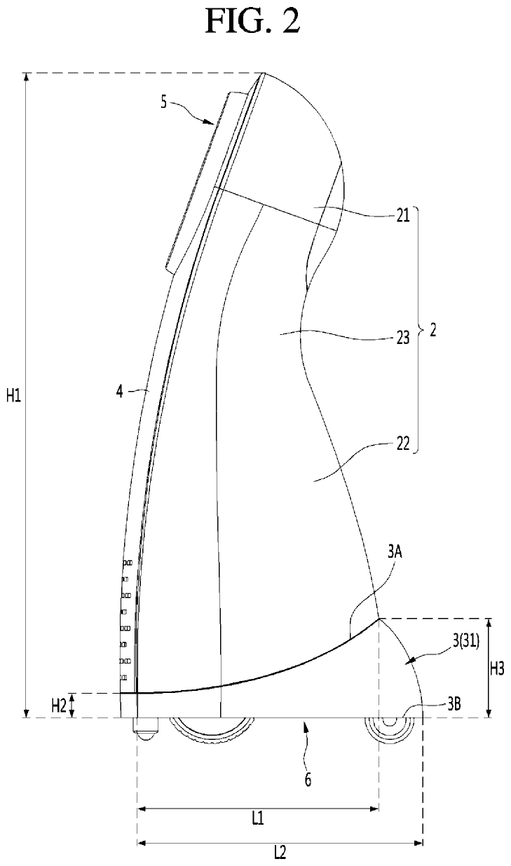

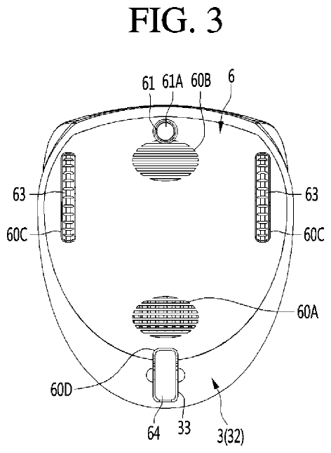

FIG. 1 is a perspective view of a robot according to an embodiment of the present disclosure, FIG. 2 is a side view of the robot according to an embodiment of the present disclosure, and FIG. 3 is a bottom view of the robot according to an embodiment of the present disclosure.

A robot according to an embodiment of the present disclosure may include a case 1, a front cover 4, and a base 6.

The case 1 may form a side and rear external shape of the robot. The case 1 may have a streamlined body having an internal space. The case 1 may be vertically elongated. At least a portion of the front surface of the case 1 may be open.

The front cover 4 can cover the open front surface of the case 1. The front cover 4 can cover the internal space of the case 1 from the front. The front cover 4 can form the front external shape of the robot. The front cover 4 may have a streamlined curved shape. The front cover 4 may be formed to be inclined or bent rearward as it goes forward.

The base 6 can form the lower external shape of the robot. The base 6 may be a plate shape.

The case 1 may be connected with the base 6 over the base 6.

In more detail, the case 1 may include a lower case 3 connected with the base 6 and an upper case 2 connected over the lower case 3.

The upper case 2 may have a streamlined body. The front surface of the upper case 2 may be open and can be covered by the front cover 4.

The upper case 2 may be vertically elongated. The height H1 of the upper case 2 may be larger than the height H3 of the lower case 3.

The upper case 2 may include a head part 21, a body part 22 disposed under the head part 21, and a connection part 23 positioned between the head part 21 and the body part 22.

The head part 21, the body part 22, and the connection part 23 may be integrally formed.

The connection part 23 may be continuously connected with the head part 21 and the body part 22 without being stepped or bending. Accordingly, the upper case 2 can have a streamlined body and the external shape of the robot can be aesthetically formed.

A head display 5 to be described below may be connected to the head part 21. The horizontal size of the head part 21 may gradually increase upward from the connection part 23 and then gradually decrease after passing a predetermined position.

The body part 22 may be positioned under the head part 21 and the connection part 23. The lower end of the body part 22 may be connected with the lower case 3.

The body part 22 may be formed larger than the head part 21. In more detail, the height of the body part 22 may be larger than the height of the head part 21 and the horizontal size of the body part 22 may be larger than the horizontal size of the head part 21.

The horizontal size of the body part 22 may gradually decreases upward.

The connection part 23 may be positioned between the body part 22 and the head part 21. The connection part 23 can connect the body part 22 and the head part 21.

The connection part 23 may be formed smaller than the body part 22 and the head part 21.

The front end edges of the head part 21, the body part 22, and the connection part 23 may be continuously connected without being stepped. Accordingly, the front cover 4 having a curved plate shape can be smoothly connected to the front end edges of the head part 21, the body part 22, and the connection part 23.

The lower case 3 may be connected under the upper case 2.

The lower case 3 may be formed such that the front portion height H2 is smaller than the rear portion height H3. The height H3 of the lower case 3 may mean the rear portion height H3.

The lower case 3 may include a circumferential surface 31 and a bottom surface 32.

The circumferential surface 31 of lower case 3 may form the lower outer circumference of the robot.

The lower end of the rear portion of the lower case 3 may protrude rearward further than the upper end of the rear portion of the lower case 3. That is, the front-rear distance L2 from the front surface to the lower end of the rear portion of the lower case 3 may be larger than the front-rear distance L1 from the front surface to the upper end of the rear portion of the lower case 3. Accordingly, a projector 7 to be described below can be disposed eccentrically rearward in the lower case 3.

The lower case 3 may be formed such that an upper end 3A of the circumferential surface 31 is bent or inclined to be lowered forward. On the contrary, a lower end 3B of the circumferential surface 31 of the lower case 3 may be horizontally formed.

The upper end 3A and the lower end 3B of the circumferential surface 31 each may have a ring shape. The size of the ring formed by the upper end 3A of the circumferential surface 31 may be smaller than the size of the ring formed by the lower end 3B. That is, the circumferential surface 31 of the lower case 3 may horizontally increase as it goes from the upper end 3A to the lower end 3B.

The bottom surface 32 of the lower case 3 may be connected with the base 6. The bottom surface of the lower case 3 may be formed toward the base 6 from the lower end 3B of the circumferential surface 31.

The bottom surface 32 of the lower case 3 may horizontally formed.

The lower surface 32 of the lower case 3 and the lower case of the base 6 may be formed in parallel and continuously connected without being stepped. Accordingly, the base 6 may form a portion of the bottom surface of the robot and the bottom surface 32 of the lower case 3 may form the other portion of the bottom surface of the robot.

However, the present disclosure is not limited thereto, and it may be possible that the lower case 3 does not include the bottom surface 32 and the lower end of the circumferential surface 31 of the lower case 3 may be directly connected to the base 6.

The upper case 2 may be connected to a portion of the upper end 3A of the lower case 3. Accordingly, the lower end of the upper case 2 can be formed to be bent or inclined downward as it goes forward in correspondence to the upper end 3A of the lower case 3.

In this case, the front case 4 may be connected to another portion of the upper end 3A of the lower case 3. Accordingly, the front portion height H2 is larger than the rear portion height H3 of the lower case 3, so the front cover 4 can be vertically elongated with the robot kept compact.

On the other hand, the front cover 4 can form the front surface of the robot. The front cover 4 may have a curved plate shape that is curved rearward as it goes upward.

The front cover 4 may be vertically elongated. The height of the front cover 4 may correspond to the height of the upper case 2.

The upper and both side edges of the front cover 4 may be connected with the front end edge of the upper case 2. The lower edge of the front cover 4 may be connected with the upper end 3A of the lower case 3.

An opening 4A in which the head display 5 is disposed may be formed at the front cover 4. The opening 4A may be formed through a portion of the upper portion of the front cover 4.

The opening 4A may be formed in a size that can avoid interference with the head display 5.

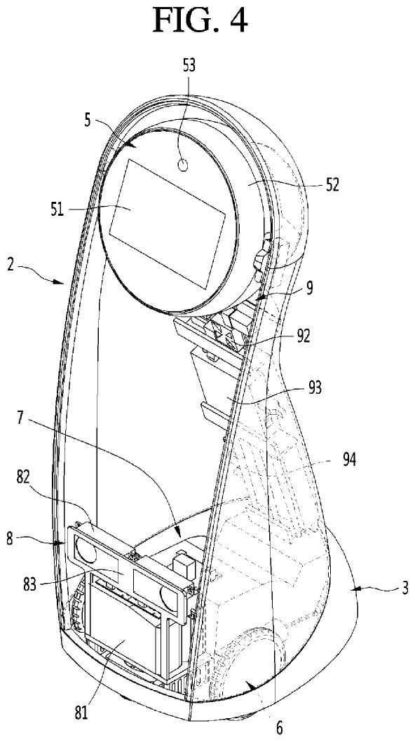

A plurality of sound holes 4B may be formed at the front cover 4. The sound holes 4B may be formed through a portion of the lower portion of the front cover 4. Sound from a speaker 82 (see FIG. 4) to be described below can be discharged through the sound holes 4B.

The base 6 can form at least a portion of the bottom surface of the robot. The base 6 may be a horizontal plate shape.

A plurality of heat dissipation holes 60A and 60B may be formed at the base 6. The heat dissipation holes 60A and 60B may be formed vertically through the base 6.

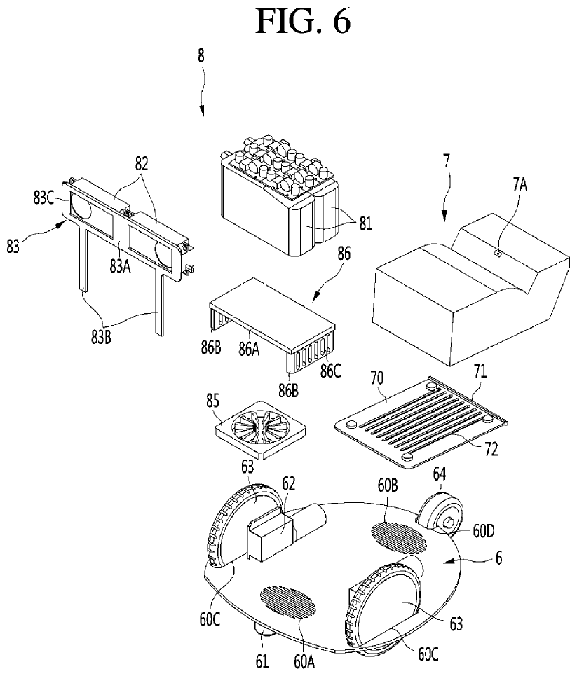

The heat dissipation holes 60A and 60B can discharge heat generated in the case 2. In more detail, airflow generated by a heat dissipation fan (see FIG. 6) to be described below can pass through the heat dissipation holes 60A and 60B.

The plurality of heat dissipation holes 60A and 60B may include a front heat dissipation hole 60A that is adjacent to the front edge of the base 6 and a rear heat dissipation hole 60b that is adjacent to the rear edge of the base 6.

Wheel through-holes 60C through which driving wheels 63 to be described below pass may be formed at the base 6. The wheel through-holes 60C may be spaced apart from the heat dissipation holes 60A and 60B and may be formed vertically through the base 6.

A pair of wheel through-holes 60C may be respectively adjacent to both side edges of the base 6.

The base 6 may have a supporting ball 61A that prevents the robot from falling forward. In more detail, a ball mount portion 61 in which the support ball 61A is mounted may be formed at the base 6. The ball mount portion 61 may be a hollow cylindrical shape protruding downward from the bottom surface of the base 6. The ball mount portion 61 may be adjacent to the front edge of the base 6.

An avoiding groove 60D that prevents interference with an assistant wheel 64 may be formed at the base 6. The assistant wheel 64 can prevent the robot from falling backward. The avoiding groove 60D may be formed at the rear edge of the base 6.

In this case, the assistant wheel 64 can be rotatably connected to the lower case 3. In more detail, an assistant wheel mount portion 33 in which the assistant wheel 64 is rotatably mounted by be formed at the rear portion of the lower case 3 and a portion of the front side of the assistant wheel 64 mounted in the assistant wheel mount portion 33 can be inserted in the avoiding groove 60D of the base 6.

On the other hand, the robot according to an embodiment of the present disclosure may include the head display 5.

The head display 5 may be connected to the case 1. In more detail, the head display 5 may be rotatably connected to the head part 21 of the upper case 2.

The head display 5 may face the front. The head display 5 can be rotated about a virtual horizontal axis elongated to the left and right. Accordingly, the head display 5 can rotate to face the front upper side, the horizontal front, or the front lower side.

The head display 5 may be disposed in the opening 4A formed at the front cover 4. Accordingly, the rotating head display 5 may not interfere with the front cover 4.

Images or videos showing the facial expressions of people can be displayed on the head display 5. Accordingly, a user can feel emotional sympathy with the robot.

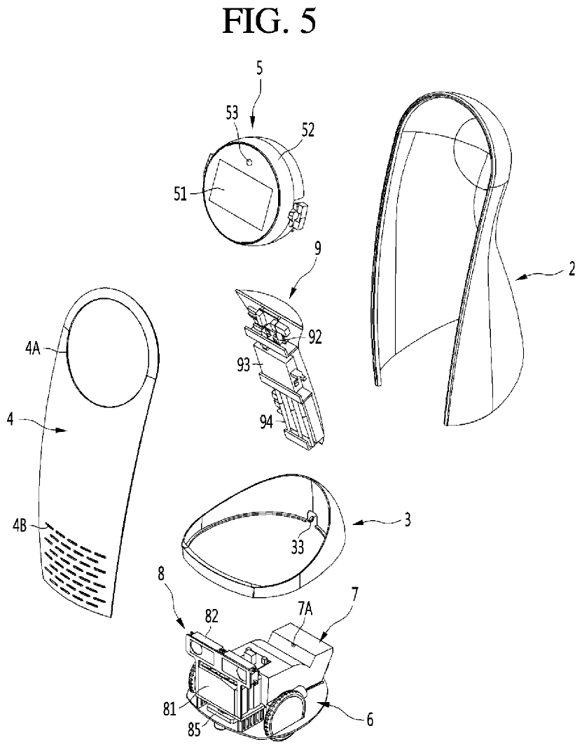

FIG. 4 is a view showing the robot according to an embodiment of the present disclosure with a front cover removed and FIG. 5 is an exploded perspective view of the robot according to an embodiment of the present disclosure.

The head display 5 may include a display 51, a housing 52, and a camera 53.

The display 51 can form at least a portion of the front surface of the head display 5. Videos or images can be displayed on the display 51.

The housing 52 can form the circumferential surface of the head display 5. The housing 52 may have a substantially hollow cylindrical shape.

The camera 53 may face the front. The camera 53 can sense a user, obstacles, etc. positioned ahead of the robot. The camera 53 may be positioned over the display 51.

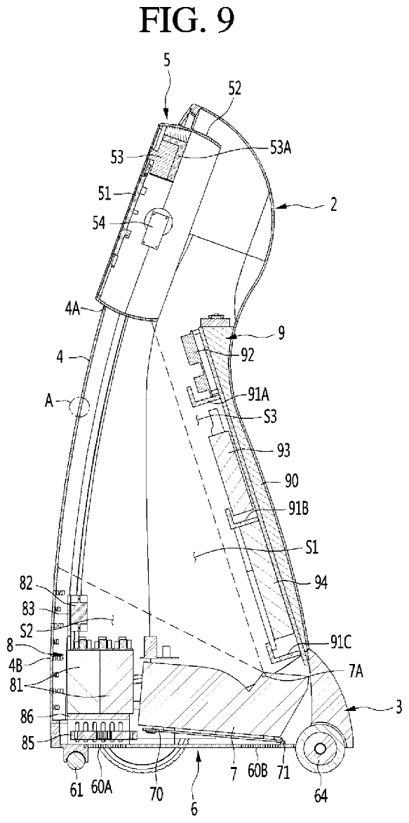

A camera mounting bracket 53A (see FIG. 9) in which the camera 53 is mounted may be disposed in the housing 52.

The head display 5 can be rotated with respect to the case 1, in more detail, the upper case 2 by a rotary motor 54 (see FIG. 9). The rotary motor 54 may be disposed in the housing 52.

The robot according to an embodiment of the present disclosure may include a projector 7 that projects videos or images to the front cover 4. Accordingly, videos or images can be displayed on the front cover 4 regardless of the head display 5.

The projector 7 may be disposed in the case 1. In more detail, the projector 7 may be disposed in the lower case 3.

The projector 7 may be seated on the base 6. Accordingly, the height of the center of gravity of the robot can be lowered and the danger of falling down of the robot can be reduced by the weight of the projector 7.

The projector 7 may be disposed eccentrically rearward in the case 1. Accordingly, it is possible to secure a sufficient focal distance such that images can be formed on the front cover 4 by light emitted from the projector 7.

The projector 7 may be disposed to face the front upper side. In more detail, a light emission part 7A of the projector 7 may be disposed to face the front upper side. Accordingly, the area where images are formed on the front cover 4 can be widened.

The robot according to an embodiment of the present disclosure may include a built-in component 8 disposed ahead of the projector 7.

The built-in component 8 may be disposed in the case 1. The built-in component 8 may be seated on the base 6.

Since the projector 7 faces the front upper side, a beam emitted from the projector 7 can travel toward the front cover 4 without being blocked by the built-in component 8 positioned ahead of the projector 7.

Accordingly, the beam of the projector 7 can smoothly reach the front cover 4 and the built-in components 8 for the operation of the robot can be efficiently arranged. Accordingly, the robot can be made compact.

The built-in component 8 may include at least one of a battery 81 and a speaker 82.

The battery 81 can supply power for the operation of the robot. The battery 81 is a part having relatively large weight, so it is preferable that the battery 81 lowers the center of gravity of the robot by being seated on the base 6.

The speaker 82 may be disposed over the battery 81. The speaker 82 may face the front and sound generated from the speaker 82 can be discharged out of the robot through sound holes 4B formed at the front cover 4.

The robot according to an embodiment of the present disclosure may include an inner bracket 9 that is positioned over the projector 7 and to which a plurality of electronic components 92, 93, and 94 is fastened.

The inner bracket 9 may be fastened to the inner rear surface of the case 1. In more detail, the inner bracket 9 may be fastened to the inner rear surface of the body part 22 of the upper case 2.

The inner bracket 9 may be disposed at an angle such that the height increases forward.

The inner bracket 9 may be positioned over the projector 7. The inner bracket 9 may vertically overlap the projector 7. Since the projector 7 faces the front upper side, the beam emitted from the projector 7 can travel toward the display region 41 of the front cover 4 without being interfered with by the inner bracket 9.

Accordingly, the beam of the projector 7 can smoothly reach the front cover 4 and the electronic components 92, 93, and 94 for the operation of the robot can be efficiently arranged. Accordingly, the robot can be made compact.

The electronic components 92, 93, and 94 may be mounted on the front surface of the inner bracket 9.

The electronic components 92, 93, and 94 may include at least one of a control board 92, a calculator 93, and a communication module 94.

The control board 92, the calculator 93, and the communication module 94 may be vertically disposed. For example, the control board 92 may be mounted on the upper portion of the inner bracket 9, the calculator 93 may be mounted on the middle portion of the inner bracket 9, and the communication module 94 may be mounted on the lower portion of the inner bracket 9.

The function of each of the control board 92, the calculator 93, and the communication module 94 is well known, so description related to the functions is omitted.

FIG. 6 is a view illustrating a base, and a projector and built-in components seated in the base according to an embodiment of the present disclosure.

The robot according to the present disclosure may include driving motors 62 and driving wheels 63 connected to the driving motor 62.

The driving motors 62 and the driving wheels 63 may be disposed at the base 6. The driving motor 62 may be disposed on the top surface of the base 6 and the driving wheels 63 may be disposed in the wheel through-holes 60C formed through the base 6.

The driving motors 62 and the driving wheels 63 each may be provided in pairs. A pair of driving motors 62 may be spaced left and right. A pair of driving wheels 63 may be spaced left and right.

At least a portion of the projector 7 may be positioned between the pair of driving motors 62. Accordingly, the installation position of the projector 7 can be lowered.

The projector 7 may be mounted on a projector seat panel 70 connected to the base 6 to be able to tilt.

The projector seat panel 70 can support the projector 7 from under the projector 7. Since the projector seat panel 70 is connected to the base 6 to be able to tilt, there is an advantage in that the installation angle of the projector 7 can be easily adjusted.

For example, a worker can fasten a supporter (not shown) having a predetermined height to the top surface of the base 6 and then connect the projector seat panel 70 to the base 6. In this case, the front portion of the projector seat panel 70 can be supported by the supporter, and the projector seat panel 70 and the projector 7 can be maintained at a predetermined angle.

In more detail, a tilting shaft 71 elongated left and right may be disposed on the rear edge of the projector seat panel 70. The tilting shaft 71 may be rotatably connected to the top surface of the base 6. In more detail, the tilting shaft 71 may be connected to the top surface of the base 60 between the heat dissipation hole 60B and the avoiding groove 60D.

A plurality of projector heat dissipation holes 72 may be formed at the projector seat panel 70. The projector heat dissipation holes 72 may be oblong holes elongated forward and rearward.

At least some of the projector heat dissipation holes 72 may face a rear heat dissipation hole 60b formed at the base 6. Accordingly, heat generated by the projector 7 can be easily dissipated through the projector heat dissipation holes 72 and the rear heat dissipation hole 60B.

Meanwhile, the robot according to an embodiment of the present disclosure may further include a heat dissipation fan 85 disposed under the built-in component 8.

The heat dissipation fan 85 generates airflow that passes through the front heat dissipation hole 60A and the rear heat dissipation hole 60B, thereby being able to easily dissipate heat generated in the robot. The airflow generated by the heat dissipation fan 85 can be suctioned into any one of the front heat dissipation hole 60A and the rear heat dissipation hole 60B and can be discharged through the other one.

The heat dissipation fan 85 may be positioned over the front heat dissipation hole 60A formed at the base 6. The heat dissipation fan 85 may be horizontally disposed.

The heat dissipation fan 85 may be disposed between a supporting body 86 supporting the built-in component 8 and the base 6.

The heat dissipation fan 85 and the supporting body 86 may be positioned between the pair of driving wheels 63 and/or driving motors 62.

In more detail, the supporting body 86 may include a supporting plate 86A horizontally formed and a supporting wall 86B formed downward from the edge of the supporting plate 86A.

The supporting plate 86A may be spaced apart upward from the base 6. The heat dissipation fan 85 may be positioned between the supporting plate 86A and the base 6.

The supporting wall 86B may be formed a both edges of the supporting plate 86A. The supporting wall 86B may space the supporting plate 86A apart from the base 6. Any one of a pair of supporting walls 86B may be positioned at side of the heat dissipation fan 85 and the other one may be positioned at the other side of the heat dissipation fan 85.

A through-hole 86C may be formed through the supporting wall 86B. The through-hole 86C may be oblong holes vertically elongated. A plurality of through-holes 86C may be formed and the plurality of through-holes 86C may be spaced forward and rearward. The airflow generated by the heat dissipation fan 85 can smoothly dissipate heat of the driving motors 62 by the through-holes formed through the supporting walls 86B.

The built-in component 8 may be supported by the supporting body 86.

In more detail, the battery 81 may be seated on the supporting plate 86A. The speaker 82 may be mounted on a speaker mounting bracket 83 fastened to the supporting body 86 and may be positioned over the battery 81.

The speaker mounting bracket 83 may include a mounting part 83A on which the speaker 82 is mounted and a leg part 83B elongated downward from the mounting portion 83A.

The mounting part 83A may be a panel shape. The mounting part 83A may be mounted on the front surface of the speaker 82.

The mounting part 83A may be elongated left and right. In this case, a plurality of speakers 82 may be disposed left and right and mounted on the mounting part 83A. This is because when a plurality of speakers 82 is vertically disposed, the beam emitted from the projector 7 may be blocked by the speakers 82.

An open hole 83C may be formed in the front-rear direction through the mounting part 83A. A sound discharge part of the speaker 82 may face the open hole 83C.

At least one leg part 83B may be formed. The leg part 83B may be a bar shape vertically elongated, but is not limited thereto.

The lower end of the leg part 83B may be fastened to the supporting body 86. The leg part 83B can space the speaker 82 apart upward from the supporting body 86.

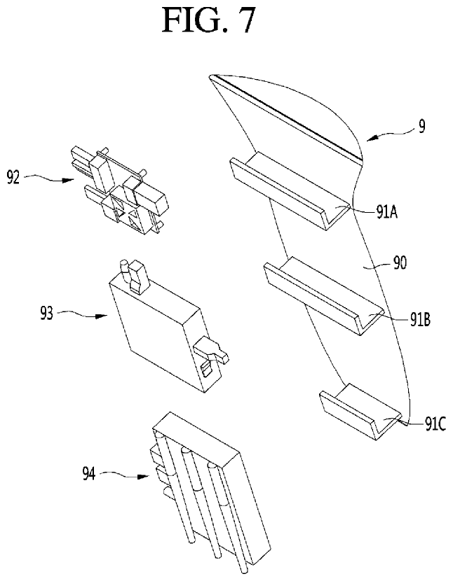

FIG. 7 is a view illustrating an inner bracket and electronic components mounted on the inner bracket according to an embodiment of the present disclosure.

The electronic components 92, 93, and 94 may be mounted on the inner bracket 9. Hereafter, an example in which the control board 92, the calculator 93, and the communication module 94 are mounted on the inner bracket 9 is described.

The inner bracket 9 may include a bracket body 90 and assistant brackets 91A, 91B, and 91C disposed on the front surface of the bracket body 90.

The bracket body 90 may be disposed at an angle such that the height increases forward.

The rear surface of the bracket body 90 may include a curved surface corresponding to the inner rear surface of the upper case 2 and the front surface of the bracket body 90 may include a flat surface. Accordingly, the electronic components 92, 93, and 94 can be easily mounted on the front surface of the bracket body 90.

The assistant brackets 91A, 91B, and 91C may be disposed on the front surface of the bracket body 90. The assistant brackets 91A, 91B, and 91C may be elongated left and right. Each of the assistant brackets 91A, 91B, and 91C may include a first part protruding perpendicular to the front surface of the bracket body 90 and a second part bending upward perpendicular to the first part from the front end of the first part.

The plurality of assistant brackets 91A, 91B, and 91C may be vertically spaced. The plurality of assistant brackets 91A, 91B, and 91C may include a first assistant bracket 91A, a second assistant bracket 91B positioned under the first assistant bracket 91A, and a third assistant bracket 91C positioned under the second assistant bracket 91B.

The control board 92 may be positioned over the first assistant bracket 91A. The calculator 93 may be positioned between the first assistant bracket 91A and the second assistant bracket 91B. The communication module 94 may be positioned between the second assistant bracket 91B and the third assistant bracket 91C.

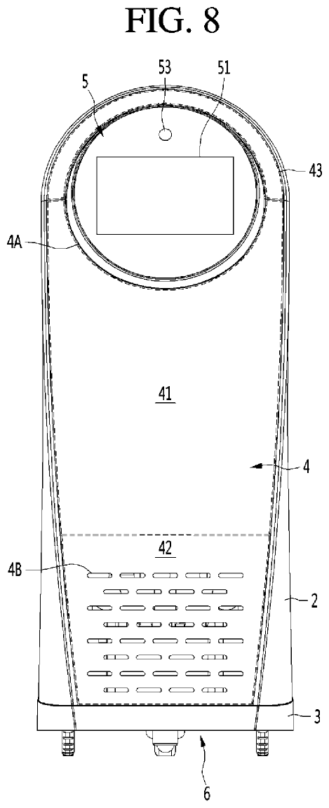

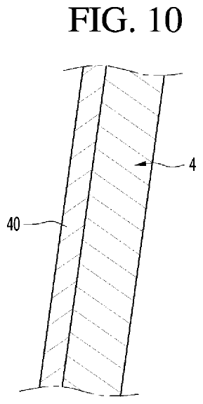

FIG. 8 is a front view showing a display region and a non-display region of a front cover according to an embodiment of the present disclosure, FIG. 9 is a cross-sectional view showing the inside of the robot according to an embodiment of the present disclosure, and FIG. 10 is a view enlarging the portion A of FIG. 9.

The front cover 4 may include a display region 41 in which images or videos projected from the projector 7 are displayed and a non-display region 42 positioned under the display region 41.

The display region 41 may mean a region that the light emitted from the projector 7 reaches. That is, videos or images projected from the projector 7 can be displayed in the display region 41.

The display region 41 can surround at least a portion around the opening 4A formed at the front cover 4. In more detail, the display region 41 can surround a portion of a lower portion around the opening 4A. That is, the upper edge of the display region 41 may be connected with the opening 4A.

Accordingly, images or videos that are displayed on the front cover 4 can be combined with the images or videos that are displayed on the head display 5 and shown to a user. For example, images or videos corresponding to facial expressions of a person may be displayed on the head display 5 and images or videos corresponding to motions of a person may be displayed on the front cover 4.

The light emitted from the projector 7 may not reach the non-display region 42. The non-display region 42 may be positioned under the display region 41.

The projector 7 and the built-in component 8 may overlap the non-display region 42 of the front cover 4 in the front-rear direction.

The sound holes 4B described above may be formed in the non-display region 42.

The area of the display region 41 may be larger than the area of the non-display region 42. That is, a half or more of the area of the front surface of the front cover 4 can function as a display and can be used as various types of user interfaces.

The front cover 4 may further include a sub-non-display region 43. The sub-non-display region 43 may be positioned over the display region 41.

The sub-non-display region 43 may surround the other portion around the opening 4A. That is, a lower portion around the opening 4A may be surrounded by the display region 41 and the upper portion may be surrounded by the sub-non-display region 43.

The internal space of the case 1 may include a first space S1 through which the light emitted from the projector 7 toward the display region 41 passes, a second space S2 positioned between the base 6 and the first space S1, and a third space S3 positioned between the first space S1 and the case 1.

Since the first space S1 is a region through which the light emitted from the projector 7 passes, it is preferable to any component is not disposed in the first space S1.

The second space S2 may be positioned between the base 6 and the first space S1. The second space S2 may be positioned under the first space S1. The built-in component 8 may be disposed in the second space S2.

The third space S3 may be positioned between the case 1 and the first space S1. The third space S3 may be positioned over and behind the first space S1. The inner bracket 9 and the electronic components 92, 93, and 94 mounted on the inner bracket 9 may be disposed in the third space S3.

Accordingly, the light emitted from the projector 7 can smoothly reach the display region 41 without being blocked by the electronic components 92, 93, and 94.

Referring to FIG. 10, an outer cover 40 having a material different from the front cover 4 may be attached to the front surface of the front cover 4. In more detail, the outer cover 40 may be attached to the front surface of the display region 41.

The front cover 4 and the outer cover 40 may have a material that transmits light at a predetermined ratio. For example, the front cover 4 may include an injection-molded plastic material and the outer cover 40 may include a fabric material. Accordingly, images or videos projected from the projector 7 can be more clearly displayed on the outer cover 40.

The above description merely explains the spirit of the present disclosure and the present disclosure may be changed and modified in various ways without departing from the spirit of the present disclosure by those skilled in the art.

Accordingly, the embodiments described herein are provided merely not to limit, but to explain the spirit of the present disclosure, and the spirit of the present disclosure is not limited by the embodiments.

The protective range of the present disclosure should be construed by the following claims and the scope and spirit of the disclosure should be construed as being included in the patent right of the present disclosure.

According to a preferred embodiment of the present disclosure, a projector is disposed behind a built-in component, so a focal distance of the projector can be secured and the robot can be made compact.

Further, since the projector is disposed to face the front upper side, the display region can be positioned over the non-display region, and the projector and the built-in component can overlap the non-display region in the front-rear direction. Accordingly, the light emitted from the projector is not blocked by the built-in component and a display region of a front cover can be maximized.

Further, the display region can surround at least a portion around the opening in which the head display is positioned. Accordingly, the videos/images displayed on the head display and the videos/images displayed in the display region can be smoothly connected.

Further, the head display region is disposed at the upper portion of the robot and the display region can surround a portion of a lower portion around the opening. Accordingly, the head display can correspond to the face of the robot and the display region can correspond to the body of the robot. Therefore, the external shape of the robot and videos/images displayed thereon can configure design similar to a human body.

Further, an outer cover having a fabric material may be attached to the front surface of the front cover. Accordingly, videos/images displayed on the display region of the front cover can be clearer.

Further, the lower end of the rear portion of the lower case may protrude rearward further than the upper end of the rear portion of the lower case. Accordingly, the projector can be disposed eccentrically rearward in the lower case and the focal distance of the projector can be secured.

Further, a plurality of sound holes through which sound from the speaker is discharged can be formed in the non-display region. Accordingly, sound can be smoothly discharged forward from the robot.

Further, the area of the display region may be larger than the area of the non-display region. Accordingly, usability of the display region can be further increased.

Further, the inner bracket and the electronic components mounted on the inner bracket can be positioned over the projector and can vertically overlap the projector. Accordingly, there is an advantage in that the internal space of the case can be efficiently used and the light emitted from the projector is not blocked by the inner bracket and electronic components mounted on the inner bracket.

Further, the projector can be seated on the base. Accordingly, the center of gravity of the robot is lowered by the projector and the robot can be prevented from falling down.

Further, at least a portion of the projector can be disposed between the pair of driving motors. Accordingly, the robot can be made vertically compact.

Further, the heat dissipation fan can be disposed under the built-in component and the heat dissipation holes can be formed at the base. Accordingly, the heat generated from the built-in component can be efficiently discharged by airflow generated by the heat dissipation fan.

Further, the rear heat dissipation hole can be positioned under the projector and the front heat dissipation hole can be positioned under the heat dissipation fan. Accordingly, the heat generated from the projector can be efficiently discharged by airflow generated by the heat dissipation fan.

Further, the projector seat panel can be connected to the base to be able to tilt. Accordingly, the installation angle of the projector can be easily adjusted.

What is claimed is:

1. A robot comprising:
a base;
a case that is disposed over the base and has an internal space;
a front cover that covers the internal space ahead of the case;
a projector that is positioned in the internal space, is disposed to face a forward upper side, and projects an image or a video to the front cover; and
a built-in component that is disposed ahead of the projector,
wherein the front cover includes:
a display region in which an image or a video projected from the projector is displayed; and
a non-display region that is positioned under the display region and overlaps the built-in component in a front-rear direction.

2. The robot of claim 1, further comprising a head display that is connected to the case and faces the front,
wherein an opening in which the head display is disposed is formed in the front cover, and
the display region surrounds at least a portion around the opening.

3. The robot of claim 2, wherein the head display is spaced upward apart from at least one of the projector or the built-in component, and the display region surrounds a portion of a lower portion around the opening.

4. The robot of claim 1, wherein the projector overlaps the non-display region in the front-rear direction.

5. The robot of claim 1, wherein an outer cover having a fabric material is attached to the front surface of the front cover.

6. The robot of claim 1, wherein the case includes:
a lower case that is fastened to the base; and
an upper case that is connected with the upper side of the lower case,
wherein the vertical length of the upper case is larger than the vertical length of the lower case.

7. The robot of claim 6, wherein the lower end of the rear portion of the lower case protrudes rearward further than the upper end of the rear portion of the lower case.

8. The robot of claim 1, wherein the built-in component includes a speaker that faces the front, and
a plurality of sound holes through which sound of the speaker is discharged is formed in the non-display region.

9. The robot of claim 1, wherein the area of the display region is larger than the area of the non-display region.

10. The robot of claim 1, further comprising an inner bracket that is disposed over the projector and to which a plurality of electronic components is fastened.

11. The robot of claim 10, wherein the internal space includes:
a first space through which light emitted from the projector to the display region passes;
a second space that is positioned between the base and the first space and in which the built-in component is disposed; and
a third space that is positioned between the first space and the case and in which the inner bracket is disposed.

12. The robot of claim 10, wherein the inner bracket is fastened to the inner rear surface of the case, is disposed at an angle such that the height increases forward, and vertically overlaps the projector.

13. The robot of claim 1, wherein the projector is seated on the base.

14. The robot of claim 13, further comprising:
a pair of driving motors that is disposed on the base; and
a pair of driving wheels that is connected to the pair of driving motors, respectively,
wherein at least a portion of the projector is disposed between the pair of driving motors.

15. The robot of claim 1, further comprising a heat dissipation fan that is disposed under the built-in component,
wherein a plurality of heat dissipation holes through which airflow generated by the heat dissipation fan passes is formed through the base.

16. The robot of claim 15, wherein the plurality of heat dissipation holes includes:
a rear heat dissipation hole that is positioned under the projector; and
a front heat dissipation hole that is positioned under the heat dissipation fan.

17. The robot of claim 1, further comprising a projector seat panel that is connected to the base to be able to tilt and on which the projector is mounted.

18. A robot comprising:
a base that has an open front surface;
a projector that is disposed in the case; and
a front cover that covers the open front surface of the case,
wherein the front cover includes:
a display region in which a video or an image projected from the projector is displayed; and
a non-display region that is positioned over or under the display region and has an area smaller than the area of the display region.

19. The robot of claim 18, further comprising a head display that is connected to the case and faces the front,
wherein an opening in which the head display is disposed is formed in the front cover, and
the display region surrounds at least a portion around the opening.

20. The robot of claim 18, wherein the projector overlaps the non-display region in the front-rear direction.
